(19) United States
(12) Patent Application Publication
(10) Pub. No.: US 2026/0215258 A1
(43) Pub. Date: Jul. 23, 2026

(54) SEMICONDUCTOR DEVICE WITH A PLURALITY OF REPLICATION UNITS AND WITH A PLURALITY OF RESISTORS AND METHOD FOR MANUFACTURING

(71) Applicant: Infineon Technologies Austria AG, Villach (AT)

(72) Inventors: Markus SEEBACHER, St.Jakob im Rosental (AT); Thomas LEITNER, Pregarten (AT)

(21) Appl. No.: 19/451,086

(22) Filed: Jan. 16, 2026

(30) Foreign Application Priority Data
Jan. 22, 2025 (DE) 102025102306.9

(51) Int. Cl. H10W 20/40; H03H 11/28; H10D 62/832; H10D 62/85; H10D 64/27; H10D 84/03; H10D 84/05; H10D 84/80

(52) U.S. Cl. CPC H10W 20/498; H03H 11/28; H10D 64/519; H10D 84/817; H10D 62/8325; H10D 62/8503; H10D 84/035; H10D 84/05

(57) ABSTRACT

Embodiments comprise a semiconductor device comprising: a gate node a drain node a source node and a gate bus, wherein the gate bus is connected to the gate node, a source structure and a drain structure, wherein the source structure is coupled to the source node and wherein the drain structure is coupled to the drain node, a plurality of replication units, wherein a respective replication unit of the plurality of replication units comprises a gate finger; wherein the gate fingers, the source structure and the drain structure are arranged to form a transistor structure, and a plurality of resistors, wherein each resistor connects one of the gate fingers to the gate bus.

### RELATED APPLICATION

This application claims priority to earlier filed German Patent Application Serial Number 10 2025 102 306.9 entitled “SEMICONDUCTOR DEVICE WITH A PLURALITY OF REPLICATION UNITS AND WITH A PLURALITY OF RESISTORS AND METHOD FOR MANUFACTURING,” filed on Jan. 22, 2025, the entire teachings of which are incorporated herein by this reference.

### TECHNICAL FIELD

Embodiments comprise a semiconductor device with a plurality of replication units and with a plurality of resistors and a method for manufacturing said semiconductor device.

Embodiments comprise a transistor, e.g. a power GaN transistor, with a novel gate bus design methodology, for example having an integrated gate resistance.

Embodiments comprise a novel gate bus design methodology for power GaN transistors.

Embodiments comprise a high voltage power transistor with GaN-technology and the design thereof.

### BACKGROUND OF EMBODIMENTS

Power transistors can be designed as a combination of a plurality of parallel small transistor portions. One can scale the size of the transistor by increasing the width of the channel (e.g. wf) and by increasing the number (e.g. n) of repetition units (e.g. “gate fingers”), for example in order to increase an amount of current that can be switched by the transistor. However, conventional large power transistors, e.g. having footprints >1 mm², do not switch as much current as they should, e.g. theoretically, do.

Furthermore, conventional gate routing designs for upscaling such transistors suffer from a decrease in stability and so the devices have a high tendency to harmful high frequency ringing. In addition, conventional approaches with different finger widths are problematic with regard to the runtimes of the gate signal and signal reflections.

Hence, there is a need for a concept for a semiconductor device achieving an improved compromise regarding a scalability of the device, e.g. with regard to a current switching capability, a footprint of the device and an R_{DSON} of the device, and regarding a stability and in particular resonance behavior of the device.

This is achieved by the subject matters of the independent claims. Further embodiments are defined by the subject matters of the dependent claims.

### SUMMARY OF EMBODIMENTS

Embodiments comprise a semiconductor device (e.g. a transistor, e.g. having a lateral transistor structure or having a vertical transistor structure) comprising: a gate node, a drain node, a source node and a gate bus, wherein the gate bus is connected to the gate node. The device further comprises a source structure and a drain structure, wherein the source structure is coupled to the source node and wherein the drain structure is coupled to the drain node. The device further comprises a plurality of replication units, wherein a respective replication unit of the plurality of replication units comprises a gate finger. The gate fingers, the source structure and the drain structure are arranged to form a transistor structure. In addition, the device further comprises a plurality of resistors, wherein each resistor connects one of the gate fingers to the gate bus.

Hence, as an optional feature, the replication units may, for example, be the gate fingers, e.g. so that the plurality of replication units is a plurality of gate fingers (e.g. a plurality of repetition units). Optionally, a respective replication unit may comprise a respective source structure and/or a respective drain structure or, for example, respective source substructures of the source structure and/or, for example, respective drain substructures of the drain structure.

As another optional feature, respective source substructures may be source fingers and respective drain substructures may be drain fingers. Hence, in other words, the source structure may comprise a plurality of source fingers, and the drain structure may comprise a plurality of drain fingers. The gate fingers, source fingers and drain fingers may hence optionally be “grouped” as replication units, so that each replication unit comprises a gate finger, a source finger of the source structure and a drain finger of the drain structure. These fingers may be arranged in an interleaved or interwoven manner, so as to form the transistor structure.

Further embodiments comprise a semiconductor device, e.g. transistor, comprising a gate node, a drain node, a source node and a gate bus, wherein the gate bus is connected to the gate node. The semiconductor device further comprises a plurality of replication units, e.g. a plurality of parallel small portions of the transistor, wherein a respective replication unit of the plurality of replication units comprises a gate finger, a source finger and a drain finger (wherein a finger is, for example, a structure with an oblong shape, e.g. a structure, which is distinctly longer in one dimension than in its other dimensions). Gate fingers, source fingers and drain fingers are arranged in an interleaved manner (e.g. in an interlocking manner; e.g. in an interwoven manner, e.g. in parallel, e.g. next to each other, e.g. in an intertwining manner, e.g. in a structure in which individual comb-like fingers are arranged next to each other in an interwoven or interlocking or intertwining manner, e.g. like teeth of two gearwheels), in order to form a transistor structure, e.g. a lateral transistor structure. Furthermore, source fingers are coupled to the source node and drain fingers are coupled to the drain node. The semiconductor device further comprises a plurality of resistors, e.g. a resistor network, wherein each resistor connects one, e.g. at least one, of the gate fingers, e.g. a respective gate finger comprising two parallel gate finger substructures, to the gate bus.

For example, in this case, the source fingers may form the source structure and the drain fingers may form the drain structure.

The resistors may, for example, be integrated resistors. The resistors may be integrated in the layer stack of the semiconductor devices. For example, the semiconductor devices may optionally comprise a diffusion barrier layer in which the resistors may be arranged. However, it is to be noted that in principle any layer may be used in order to implement the resistors. The principles of embodiments may allow for a high flexibility regarding the implementation (e.g. positioning) of the resistors. For example, other GaN technologies which may mainly or only use Aluminum may have no diffusion barrier layer. Nevertheless, in such cases respective resistors may be implemented elsewhere.

It was recognized that an implementation of additional resistors, which may form a resistive network, between the gate fingers and the gate bus allows adapting an input resistance of the gate fingers, which may attenuate high frequency oscillations and which may allow a matching of current densities between different finger widths. In other words, these newly introduced resistors may act as ballast for high frequency oscillations, and may match the current densities between different finger widths.

For example, the stability may be increased with a respective series resistor for each gate (e.g. for each gate finger, or at least for a pair or set of gate fingers), so reflected waves may be damped or attenuated before entering the gate bus, which may further increase the stability (e.g. by reducing the amplitude of each reflection so as to achieve internal damping or attenuation for each finger). The resistors may, optionally, be weighted according to the finger width differences in the design.

This may, for example, enable to exploit advantages of a double-sided gate bus structure (or of a ring bus structure), whilst mitigating respective disadvantages, such as ringing issues.

Here, it is to be noted that the “width” of a respective gate finger may correspond to the width of the channel and may hence correspond to the longest edge of a respective gate finger. Hence, “width” may be understood as a length of the finger, in conjunction with the term “channel width”. For example, a channel width of the transistor area of the device may be wf=1.1 mm and hence the gate fingers may have a width (hence gate finger width wf) or respectively finger length of 1.1 mm.

In other words, regarding a “channel width” or “channel length” (or respectively “finger width” or “finger length”), in a device cross-section, the naming may be easy to understand but if one looks on top of the structure the “width” of the channel may appear to be a “long-ish” dimension. Hence, although being, for example, a longer dimension of a respective finger, the dimension is called herein finger width, e.g. wf=gate finger width.

Furthermore, it is to be noted that a replication unit may be considered a set of at least one gate finger, source finger and drain finger, wherein a repetition unit may be considered a gate finger.

Furthermore, it was recognized that the resistors may enable a decoupling (or a reduction of a coupling or a reduction of an influence) of inactive gate fingers. The last and first gate finger (e.g. in the lateral or vertical plane of the active area) of the device may have an additional gate-diode-area, which may not contribute to the saturation current in high current cases. This diode may be called inactive gate diode. The cathode of the diode does, for example, not see the channel potential. Instead, it sees, for example, source potential, which means this diode may have a higher effective voltage bias, which may increase the current a lot. This may furthermore decrease the voltage of all other gate fingers. For example, by increasing a resistance of a respective gate finger using the resistors, e.g. to a level 10 times higher than an input resistance without the resistors, the last and first finger may, for example, only be visible from the outside as a fraction of the total resistance. As an example, the total resistance may be (e.g. substantially) built up by 80 parallel resistors. Then, the last and first finger may, for example, only be visible from the outside as a fraction of 2/80 of the total resistance. Hence, only 1.2% of current is, for example, flowing into this first and last gate finger. Here, it is to be noted that embodiments may comprise less than 80 gate fingers or even more than 80 gate fingers, e.g. 100 gate fingers.

Hence, such a semiconductor device may achieve an improved compromise regarding a scalability of the device, e.g. with regard to a current switching capability, a footprint of the device and an R_{DSON} of the device, and regarding a stability and in particular resonance behavior of the device.

### BRIEF DESCRIPTION OF THE DRAWINGS

The drawings are not necessarily to scale, emphasis instead generally being placed upon illustrating the principles of embodiments. In the following description, various embodiments are described with reference to the following drawings, in which:

FIG. 1 shows a schematic view of an ideal (e.g. idealized) system comprising a semiconductor device according to embodiments;

FIG. 2 shows a schematic view of the system of FIG. 1 with included parasitics;

FIG. 3 a)-d) shows schematic views of a) circuitry of a system for a semiconductor device according to embodiments, as discussed in the context of FIGS. 1 and 2, b) a model of a semiconductor device, c) an arrangement of gate, source and drain fingers according to embodiments, and d) a schematic sectional view of a semiconductor device according to embodiments;

FIG. 4 shows a schematic view of a semiconductor device according to embodiments;

FIG. 5 shows a schematic view of a model of a semiconductor device with a double-sided gate bus according to embodiments;

FIG. 6 a)-b) show schematic views of a semiconductor device with a doubled-sided gate bus according to embodiments;

FIG. 7 shows the schematic view of the model of FIG. 5 with highlighted potential internal current loops;

FIG. 8 shows a schematic view of a model of a semiconductor device with optional electrical interruptions according to embodiments;

FIG. 9 shows a schematic detail view of a model for gate finger interaction according to embodiments; and

FIG. 10 shows a schematic view of a model for one finger unit with double-sided gate bus according to embodiments.

### DETAILED DESCRIPTION OF THE EMBODIMENTS

Equal or equivalent elements or elements with equal or equivalent functionality are denoted in the following description by equal or equivalent reference numerals even if occurring in different figures.

In the following description, a plurality of details is set forth to provide a more throughout explanation of embodiments. However, it will be apparent to those skilled in the art that embodiments may be practiced without these specific details. In other instances, well-known structures and devices are shown in block diagram form rather than in detail in order to avoid obscuring embodiments. In addition, features of the different embodiments described herein after may be combined with each other, unless specifically noted otherwise.

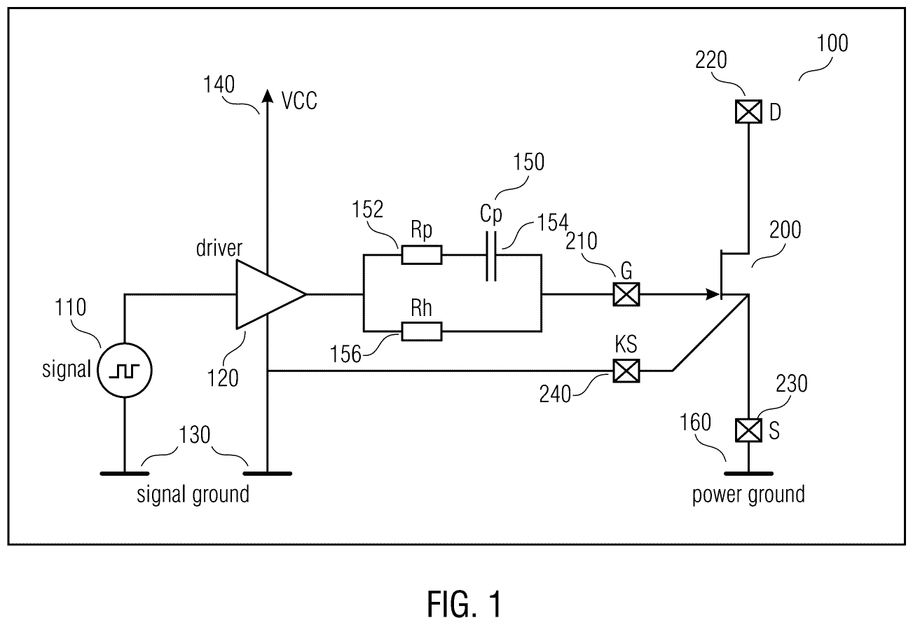

In order to facilitate understanding embodiments, reference is made first to FIG. 1 to 3. FIG. 1 shows a schematic view of a system (e.g. an ideal or idealized system) comprising a semiconductor device according to embodiments.

FIG. 1 shows a system 100 (e.g. an ideal or idealized system) comprising a signal generator 110 and a driver 120, which are coupled with a signal ground 130. Furthermore, a driver supply provides a supply voltage V_{CC} 140 to the driver 120. The system 100 optionally comprises a gate network 150 with a peak current limiting resistor, Rp, 152 and serially connected thereto a peak current path capacitor, Cp, 154, in parallel to a hold current resistor, Rh, 156. The system further comprises a semiconductor device 200 (for example a GaN HEMT) having a gate node 210 (e.g. a gate pin), a drain node 220 and a source node 230. As an optional feature, the device 200 further comprises a kelvin source pin (e.g. used for gate drive or even for gate drive only), KS, 240.

The network 150 is coupled with an output of the driver 120 and the gate node 210, the optional kelvin source pin 240 is coupled with the signal ground 130 and the source node 230 is coupled with a power ground 160. The setup shown in FIG. 1 may be considered a standard wiring of the semiconductor device 200.

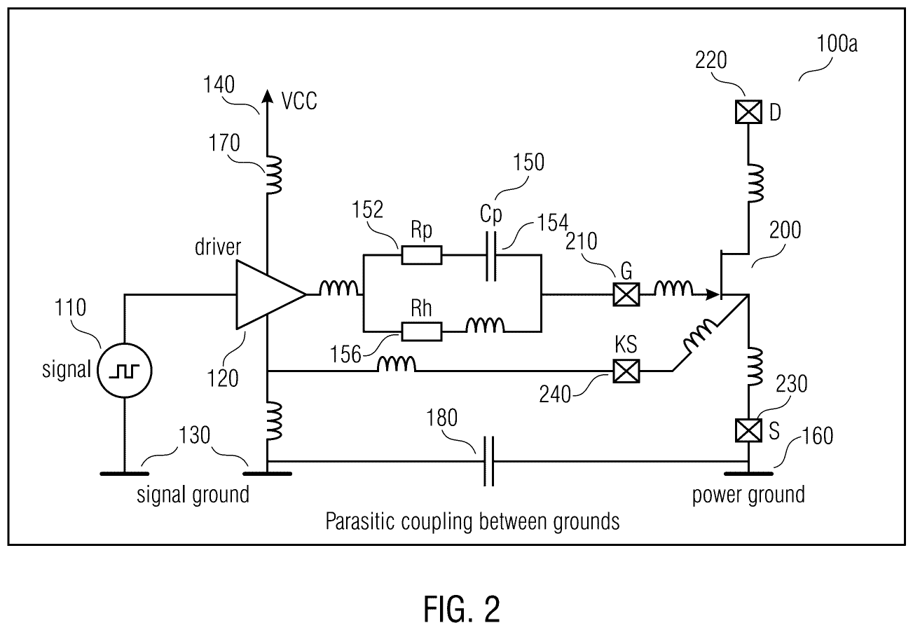

FIG. 2 shows a schematic view of the system (indicated as system 100a) of FIG. 1 with included parasitics, e.g. associated with PCB (Printed Circuit Board) and package. In other words, FIG. 2 may show the outer system with parasitics PCB and package. As shown, inductive (170), as well as capacitive (180) coupling, e.g. parasitic coupling, may affect the system behavior.

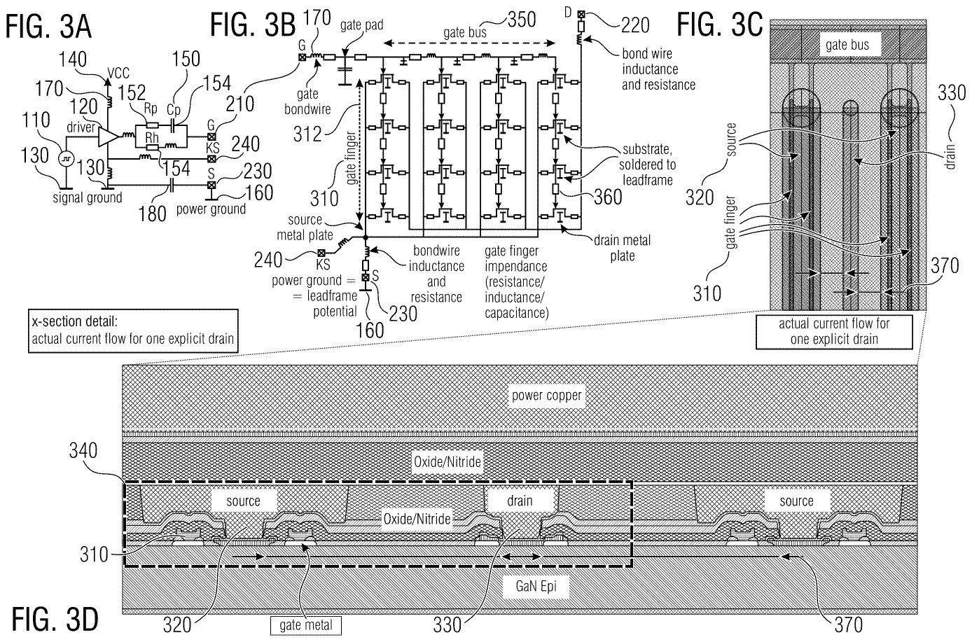

FIG. 3 shows schematic views of a) circuitry of a system for a semiconductor device according to embodiments, as discussed in the context of FIGS. 1 and 2, b) a model of a semiconductor device (e.g. a lumped model, e.g. a transistor layout, e.g. in the form of a 4 by 4 model), c) an arrangement of gate, source and drain fingers according to embodiments, and d) a schematic sectional view of a semiconductor device according to embodiments. A layer stack of a device according to embodiments may correspond to the sectional view of FIG. 3 d), e.g. as disclosed in US 2023163209 A1. For example, in addition to such a BEOL layer stack, embodiments may further comprise a diffusion barrier (e.g. a diffusion barrier layer, e.g. with a diffusion barrier for FB (wherein =Metal1=Copper).

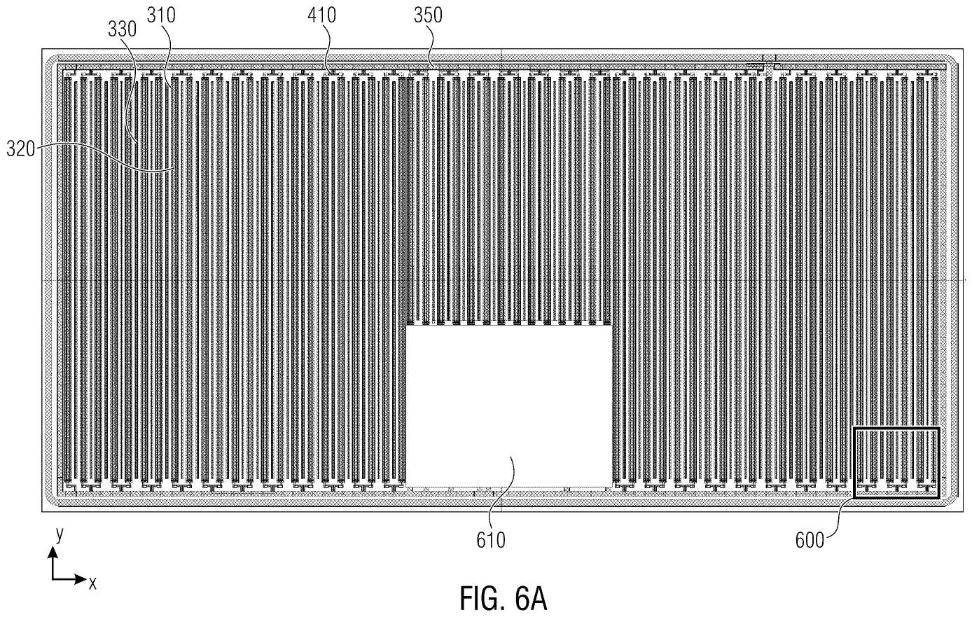

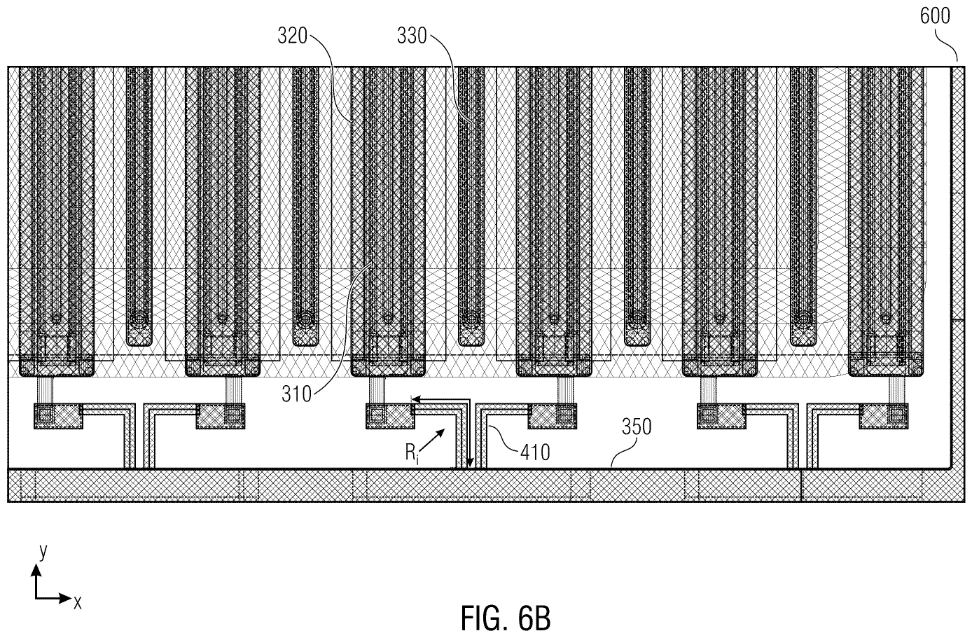

The FB may be the metal1, (e.g. known under many names). In the end, FB or respectively metal1 may be the first low impedance metal that can really carry current, and it is used for the connections from source/drain to M2 as well as a routing layer for the gate signal or other signals.). For example, it is usual to use a diffusion barrier as soon as copper is used, otherwise the copper can “cheat” its way through the insulation by forming dendrites (e.g. tendrites). Furthermore, to deposit copper, a “seed” layer or liner is usually placed to give the copper a chance to “grow” in the right places. One can think of it like growing crystals, the copper may use or may even need, for example, a metallic conductive surface to grow on, and this is usually the liner. In this regard, reference is made to FIG. 6 b), which will be discussed in more detail in the following, showing the resistors (e.g. Rᵢ) as upside down “L” shaped structures, see e.g. elements 410.

FIG. 3 c) may be understood as a top view of the layer stack shown in FIG. 3 d). Hence, a semiconductor device may comprise gate fingers 310, source fingers 320 and drain fingers 330. These fingers may be arranged as replication units 340, forming small portions of the semiconductor device. Hence, a plurality of replication units may be arranged side by side, e.g. in a lateral plane, as indicated in FIG. 3 d), in order to form the device.

As shown in FIG. 3 b) and c), the gate fingers, source fingers and drain fingers are arranged in an interleaved manner, in order to form a transistor structure.

The specific layers as shown in FIG. 3 d) are to be understood as examples. Other materials and layer arrangements are possible as well. As mentioned before, in particular a diffusion barrier layer may be provided in the stack.

As shown in FIG. 3 b), the semiconductor device 200, or respectively a portion thereof, may be modeled using a lumped model of a transistor layout (4 by 4 model). A gate bus, as shown in FIG. 3 c), is indicated with reference sign 350. Accordingly, the gate bus 350 is connected to the gate node 210. The gate fingers 310 are modeled as a sequence of individual transistors. Furthermore, in addition to inductive parasitics 170, resistive effects 190 are modeled as well. In particular, an impedance of the gate fingers 310 is modeled, see 360, which may represent a resistance, inductance and/or capacitance or a combination thereof.

As an example, a substrate of the device may be soldered to a lead frame. However, this is to be understood as an optional feature. As shown, the power ground 160 may be identical to the lead frame potential. Furthermore, at the gate node 210, an influence of the gate pad and the gate bond wire may be modeled using a set of an inductance, resistances and a capacitor. Furthermore, bond wire inductances and resistances may as well be considered for the drain node 220 and source node 230.

Regarding, FIG. 3 d), it is to be noted that the source fingers 320 are coupled to the source node 230 and the drain fingers 330 are coupled to the drain node 220.

The model of FIG. 3 b) shows a single-sided gate bus. A flow of current is indicated with arrows 370 (e.g. showing a current flow for one drain finger 330).

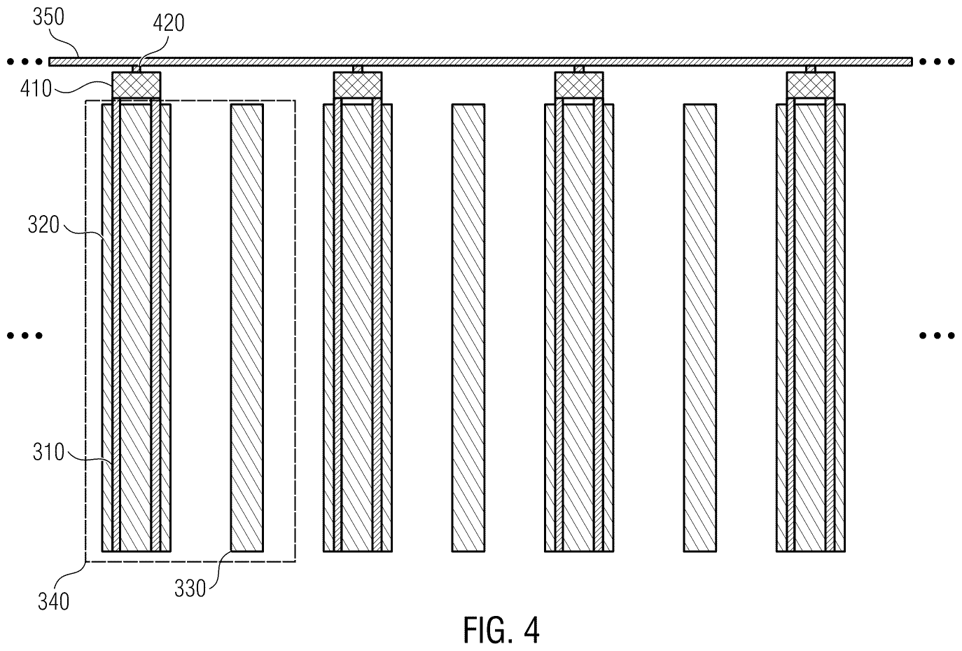

Reference is made to FIG. 4, showing a schematic view of a semiconductor device according to embodiments. Now, in addition to the structure as discussed in the context of FIG. 3 (with or without the optional elements and features), embodiments may further comprise, see FIG. 4, a plurality of resistors 410, e.g. a resistor network, wherein each resistor connects one, e.g. at least one, of the gate fingers, e.g. a respective gate finger optionally comprising two parallel gate finger substructures, to the gate bus 350.

This approach is applicable to single-sided gate buses as well as double-sided gate buses or ring gate buses. Hence, embodiments comprise a novel gate bus design methodology for power transistors, such as GaN transistors. In particular, embodiments allow for improved designs for high voltage power transistors, for example with GaN-Technology.

Optionally, as shown in FIG. 4, the gate bus comprises a plurality of gate bus junctions, 420, e.g. branch points of the gate bus, wherein a respective resistor 410 is arranged between a respective gate bus junction and a respective gate finger 310. Between the fingers, the current may flow via a semiconductor material (not shown), e.g. as indicated in FIG. 3.

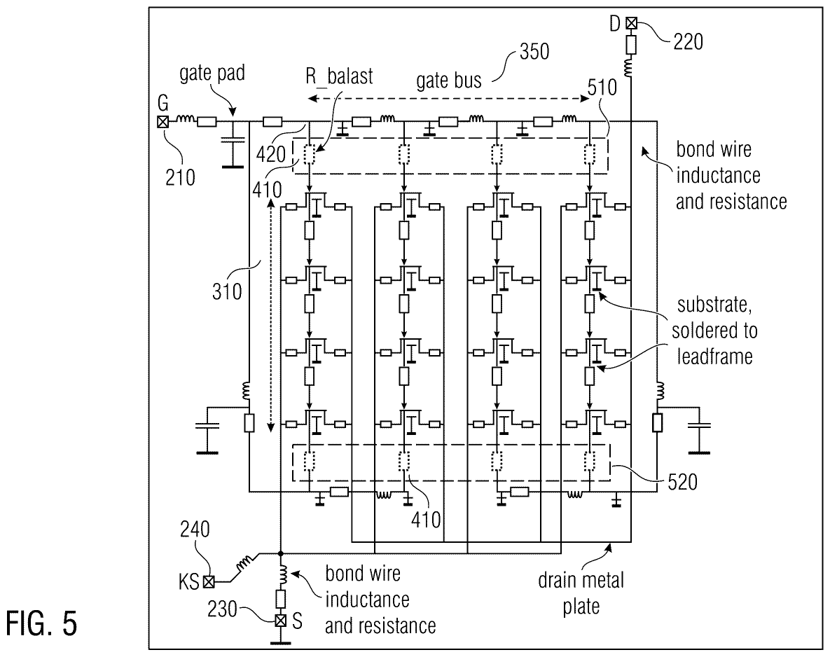

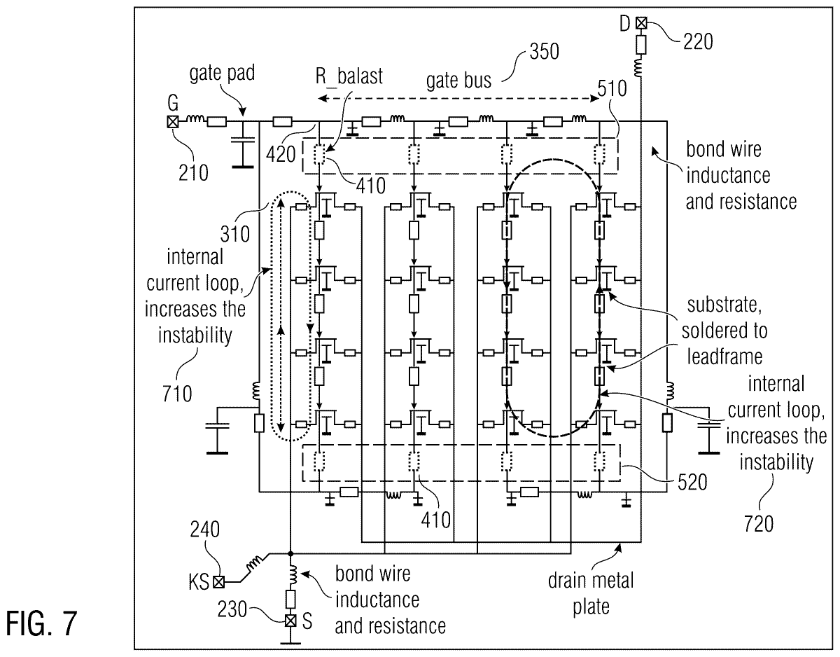

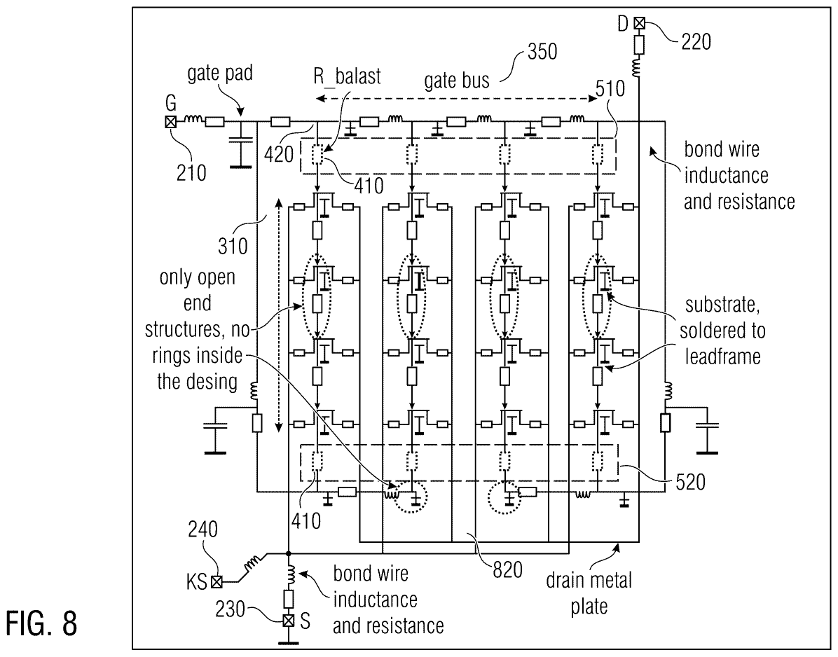

The plurality of resistors according to embodiments is further highlighted in FIG. 5 and 7 to 8, showing schematic views of models of semiconductor devices according to embodiments. Hence, FIG. 5 and 7 to 8 may show different versions of embodiments. FIG. 5 shows a schematic view of a model of a semiconductor device with a double-sided gate bus according to embodiments. FIG. 7 shows the schematic view of the model of FIG. 5 with highlighted potential internal current loops and FIG. 8 shows a schematic view of a model of a semiconductor device with optional electrical interruptions according to embodiments.

As an optional feature, the semiconductor devices according to embodiments, modeled as shown in FIG. 5 and 7 to 8, comprise double-sided gate buses. In other words, according to the embodiment of FIG. 5, the gate fingers 310 are coupled to the gate bus 350 via at least two connection paths, wherein the two connection paths are, for example, coupled to a respective gate finger at opposite ends of the gate finger (e.g. lengthwise or widthwise opposite ends of the gate finger). This may allow improving potential distributions in the gate fingers 310.

Kelvin source pin 240, as well as the specifics of the substrate, as being soldered to the lead frame, are optional.

In other words, as shown in FIG. 5, for a double-sided (e.g. compared to a single sided gate bus), gate fingers 310 of the active structures are connected by both sides (double-sided) instead of only on side (single sided) only, for example, as shown in FIG. 3 b). Using double-sided gate buses, an increased gate overdrive for transistor parts far away from the gate bus may be achieved, leading to an increased I_{DSAT}. Furthermore, a more even turn on may be achieved, which may also impact lifetime (e.g. increase lifetime). Furthermore, the transistor may be faster, e.g. as compared to a single sided gate bus. In addition, a thermal distribution may be improved.

In particular, a double-sided connection may lower gate finger resistances significantly, e.g. for example by a factor of 4. A result thereof may be the above-discussed improved potential distribution in the gate fingers and as well a more balanced drain current distribution.

However, conventionally, a double-sided design may lead to problems regarding oscillations in the transistor device, such as ringing. In addition, I_{dsat} may be lower than theoretically expected because of dead gate fingers, e.g. of first and last gate fingers in a lateral plane comprising a plurality of neighboring replication units, which have additional gate-diode-area are which do not contribute to the saturation current in high current case. This diode is called inactive gate diode.

However, the resistors 410 allow achieving an improved current distribution, mitigating the effect of the additional gate-diode area of such first and last gate fingers.

Nevertheless, embodiments comprising single-sided gate buses may be advantageous for slower transistors, since they may provide more intrinsic damping and may be easier to handle (e.g. to control).

To sum up, regarding a double-sided gate bus or ring design, a major problem may be instability in the system. Turn on may show ringing and can lead to oscillations in steady state too, but increases the I_{DSAT} value at stable setups. Stable setups were only possible according to other approaches for small die sizes (e.g. below 3 mm²), and not for the low ohmic (<140 mΩ). However, now embodiments allow solving said stability issues and further allow addressing even small die sizes as low ohmic designs. Hence, embodiments as shown in FIGS. 5 to 8 may solve problems of double-sided gate buses as well as of single-sided gate buses as shown in FIG. 3 b). A resistive path of the gate signal is indicated with arrow 312.

Furthermore, as an optional feature, as shown in FIG. 5 and in line with the double-sided gate bus design, the plurality of resistors may comprise a first subset, 510, of resistors, e.g. a first resistor network and a second subset, 520, of resistors, e.g. a second resistor network. A respective gate finger 310 may comprise a first end and a second end, wherein the second end is lengthwise opposite to the first end and each resistor of the first subset of resistors connects a first end and each resistor of the second subset of resistors connects a second end of one of the gate fingers 310 to the gate bus 350, in order to improve potential distributions in the gate fingers.

Reference is made to FIG. 6 a) and b) showing a semiconductor device with a doubled-sided gate bus according to embodiments. As shown in FIG. 6 a), some of the gate fingers may have different sizes (see e.g. middle of FIG. 6 a) compared to left and right side). FIG. 6 b) shows a magnified section 600 of FIG. 6 a).

The area 610 in the “lower middle” of FIG. 6 a) is optional and may be used for sense structures. It may, for example, comprise ESD protection diodes, and chip ID markings.

Referring to FIG. 6 a), it is important to note that different finger widths may be present. In other words, in the end, it may not really be important why different finger widths are present, an important aspect of embodiments may be the adjustment of the resistance to match the same time constant, e.g. τ=R*Cgs. This time constant may, for example, define substantially (e.g. more or less), which parts are switched on at which time, and one can make use of this to control the switching behavior, either all switching at the same time or one may intentionally delay some parts to get a smoother transition, up to the application use case.

The outer ring shown in FIG. 6a) is the seal ring of the chip. This seal ring is used to prevent chip cracks at the edges due to mechanical stress during sawing and handling during the pre-assembly and assembly (packaging).

Therefore, as an optional feature, a resistance of a respective resistor 410 may be set in dependence on a size of a respective gate finger 310, in order to match current densities between different gate fingers having different gate finger sizes, e.g. sizes along a long axis of a respective finger (e.g. in a y-direction). This may allow matching the current densities between different finger widths (or lengths) or channels widths respectively.

Furthermore, as apparent by FIG. 6 a), using a large number of replication units, significant phase shifts of the gate signal may be present. However, as an optional feature, such signal length or phase shift errors may be leveled out by using different resistors per gate finger 310 (or at least per set of gate fingers) to match timing again. Hence, optionally, the resistors 410 may be configured to mitigate, e.g. to reduce, gate signal runtime differences for the gate fingers 310. In other words, an influence (signal length/phase shift) of the trace length of the gate runner may be mitigated (Example: 1 mm trace ~10 ps->leads to >100 ps for large design->Can be leveled out by using different resistors per gate finger to match timing again).

In general, the resistors 410 may be configured to adapt (e.g. to change, e.g. to increase, e.g. to reduce) gate signal runtime differences for the gate fingers, e.g. in comparison to a setup without said resistor. For example, for some applications, an artificial increase of the runtime for a weak/soft turn on/off behavior may be desired. This may, for example, be applied in particular for motor drive applications.

Hence, to sum up, conventionally:
1. Large power transistors, e.g. >1 mm² (for example regarding a lateral or vertical footprint), do not switch as much current as they should do (for example as they should theoretically do). Or in other words they do not scale with the total finger-width (e.g. the finger widths along a y-axis, see FIG. 6), for example, they do not scale sufficiently as to be expected with an increase in total finger-width. It was recognized that the internal gate resistance is very high in high finger width devices. To mitigate this problem, optionally according to embodiments, the gate routing may be changed to be more low-ohmic, by connecting the fingers from both sides (see e.g. gate bus routing in FIG. 5 in comparison to FIG. 3 b)). This may increase the maximum possible saturation current, for example a lot, but may also decrease stability and so the devices may have a high tendency to harmful high frequency ringing.
2. Further problems that are, for example, due to the design with different finger widths (see e.g. gate fingers in the middle of FIG. 6a) compared to the fingers on the left and right), are runtime differences of the gate signal, possible reflections, and also that the last and first finger has an additional gate-diode-area, which may not contribute to the saturation current, for example, in high current case. This diode is called inactive gate diode, this cathode of the diode does, for example, not see the channel potential, instead it may, for example, see source potential, which means this diode has a higher effective voltage bias, which increases the current, for example a lot. This may furthermore decrease the voltage of all other gate-fingers too. This may lead to less gate voltage on the overall transistor.

For example, in FA (failure analysis) it was shown via FIB (Focused Ion Beam)-Cut that this may lead to a 7% loss in DC saturation current due to this effect. But simply cutting these fingers away will increase the R_{DSON}, so it would cost additional active area ~3%, this depends on the gate finger count of the design.

Hence, according to embodiments a specific resistive network may be introduced in the gate routing. These introduced resistors may act as ballast for high frequency oscillations and may match the current densities between different finger widths. Therefore, resistors 410 may be addressed herein as R_balast. For example, the resistors 410 may be configured to mitigate oscillations above 30 MHz. For example, the design of the resistors, 410, can be performed according to a low-pass filter. Depending on the application, the cut-off frequency can range from a few 10 MHz to a few 100 MHz.

Therefore, embodiments may address or even solve some or even all of the above-discussed problems.

In the following, this benefit regarding dead or inactive gate fingers is to be further highlighted. As shown in FIG. 6 a), a set (the set for example comprising the plurality of (e.g. all) replication units) of replication units, e.g. the plurality of replication units, may be arranged side by side in a common plane, wherein the set of replication units comprises a first gate finger at a first side of the set of replication units (e.g. the first gate finger on the left side of FIG. 6 a)) and a last gate finger at a second side, opposite to the first side of the set of replication units (e.g. the last gate finger on the right side of FIG. 6 a)), within the common plane. The first gate finger and the last gate finger respectively may hence only have one neighboring gate finger in the common plane (e.g. so that the first and the last gate finger do not have a second neighboring gate finger in the common plane; e.g. so that the first and last gate fingers form inactive gate diodes. Furthermore, the resistors 410 connected to the gate fingers of the set of replications units may be configured to mitigate, e.g. to reduce, differences between (e.g. to level, e.g. to equalize, e.g. to match) input resistances of gate fingers between the first and last gate finger and of the first and last gate finger (e.g. in order to mitigate input resistance differences of individual gate fingers, e.g. in particular differences of input resistances of gate fingers between the first and last gate finger compared to input resistances of the first and last gate finger). Hence, for example, a substantially even current distribution in the gate fingers may be achieved.

In this regard, it is to be noted that the resistors for the last and first gate finger may for example, be substantially or in the first approximation the same (e.g. regarding their resistance) as all others. However, since the total resistance is built up by the number of parallel resistors, for example, by 80 parallel resistors, the last and first finger are only visible from the outside as a fraction of total resistance, e.g. the fraction 2/80. Hence for this example, it would be just approximately 1.2% current flowing into this first and last gate finger.

The resistors may decouple the inactive gate fingers (e.g. first and last gate finger) with a resistance, for example, >10 times higher than the visible input resistance. Furthermore, the stability may be increased with such series resistors 410 for each gate, so any reflected wave may be or will be damped or attenuated before entering the gate bus 350, which may further increase the stability. As discussed above, the resistors may, for example, be weighted accordingly to the finger width differences in the design.

Next, reference is made to FIG. 7. FIG. 7 shows the schematic model of FIG. 6, wherein additionally, current loops 710 and 720 are indicated. It was further recognized that a stability of the semiconductor device may be further increase if these loops are structurally changed.

Reference is made to FIG. 8. As shown in FIG. 8 and as previously discussed for FIG. 5, optionally, the device may comprise a first subset, 510, of resistors, e.g. a first resistor network and a second subset, 520, of resistors, e.g. a second resistor network. Hence, a respective gate finger 310 may comprise a first end and a second end, wherein the second end is lengthwise opposite to the first end and each resistor of the first subset of resistors connects a first end and each resistor of the second subset of resistors connects a second end of one of the gate fingers 310 to the gate bus 350, in order to improve potential distributions in the gate fingers. Furthermore, as another optional feature, a respective gate finger 310 may comprise an electrical interruption 810 between the first and second end.

As another optional feature, the gate bus 350 comprises an electrical interruption 820. Hence, embodiments may comprise open end structures, in order to reduce a number of ring paths for current oscillations.

To sum up for FIGS. 5, 7 and 8. The model of in FIG. 5 shows a lumped model of a transistor layout, e.g. a proposed layout (4 by 4 model), double-sided connected, with open ring structure and R_balast, the model of FIG. 7 shows a lumped model of a transistor layout, e.g. a proposed layout (4 by 4 model), double-sided connected, with open ring structure and R_balast showing in addition the current loops for possible oscillations and the model of FIG. 8 shows a lumped model of a transistor layout, e.g. another proposed layout (4 by 4 model), double-sided connected, with open ring structure, with “no loop” (because of the interruptions) and R_balast. The model of FIG. 8 may be considered a target version for embodiments.

However, regarding FIGS. 5 to 8, it is to be noted again, that the double-sided gate bus 350 or ring bus are only options according to embodiments. The single-sided bus, e.g. as shown in FIG. 3, can also tend to oscillate or require runtime adjustments. Therefore, it is to be highlighted, that embodiments may as well comprise the structure as modeled in FIG. 3 b), with only the first set 810 of resistors implemented between the gate fingers 310 and the single-sided gate bus 350.

Interruptions 810 may be achieved or implemented by dividing a respective transistor cell, for example in y-direction (e.g. in a lengthwise direction of the gate fingers). For example, in case the gate width is to be 2 mm, two 1 mm gate fingers may be place, the repetition or replication unit in x-direction (e.g. orthogonal to the y-direction) may remain. Electrically, conductor tracks for source and drain must or should continue (e.g. should not be electrically interrupted), however this may be achieved by a simple “routing”, for example using a copper “FB” and corresponding diffusion layer and liner.

Furthermore, it is to be noted that “open-end” structures (e.g. such as an interrupted gate bus 350, see 820), as implemented in the approach shown in FIG. 8 is an optional mean to mitigate oscillations. As indicated in FIG. 7, one problem may be undesired oscillations because of parallel paths. Hence, a use of “open-end” structures according to embodiments may prevent or at least mitigate superpositions of signals with different runtimes.

Furthermore, with regard to the gate signal routing as shown in FIGS. 5 to 8, it is to be noted that embodiments are not limited to the specific routing shown. For example, an interruption 820 may be present at a different position of the gate bus. In this regard, it is to be noted that the interruption, the gate signal pick-up for the gate fingers, as well as runtime and symmetry play together an important role for the behavior of the device. Hence, a respective interruption may be present at different places for different designs. For example, for a design, in which the gate pad is in the middle, the interruption, e.g. a slit, may be arranged in the middle.

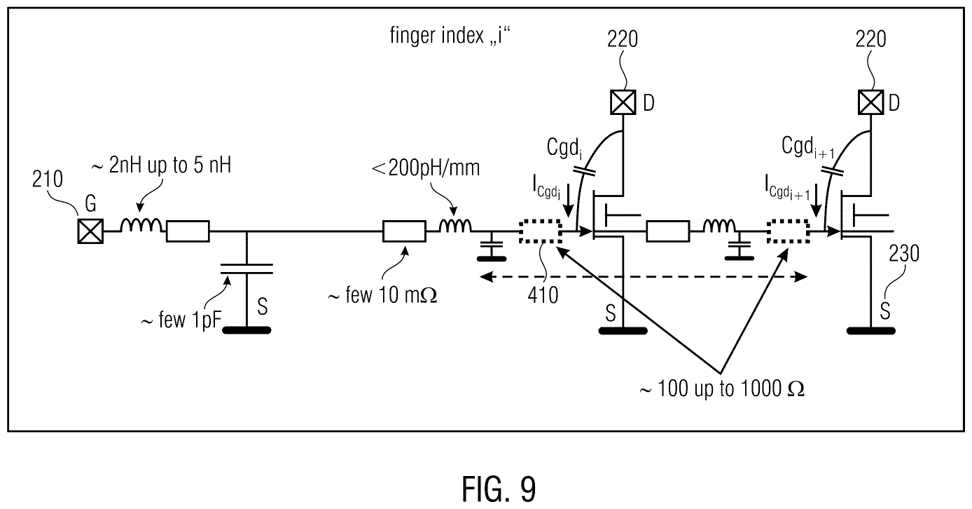

Next, reference is made to FIG. 9. FIG. 9 shows a schematic detail view of a model for gate finger interaction (e.g. as runtime oscillator) according to embodiments. The specific dimensioning of the components is to be understood as examples only.

Signal runtime difference may, for example, be one pitch of the transistor. The current I_{cgd} may discharge the gate bus (voltage drop). This is dV/dt dependent. The original signal (gate driver pulse) may get super positioned by this additional signal which is coming from each gate finger at a different position (time).

For the constructive interference of all pulses the frequency was found as beating frequency. This feedback loop comprises or consists out of the C_{gd} of the adjacent transistor fingers as well as the connection impedance between the adjacent fingers.

To damp or attenuate this feedback loop one needs to damp inside the loop, which is the red marked resistor 410 and part of embodiments.

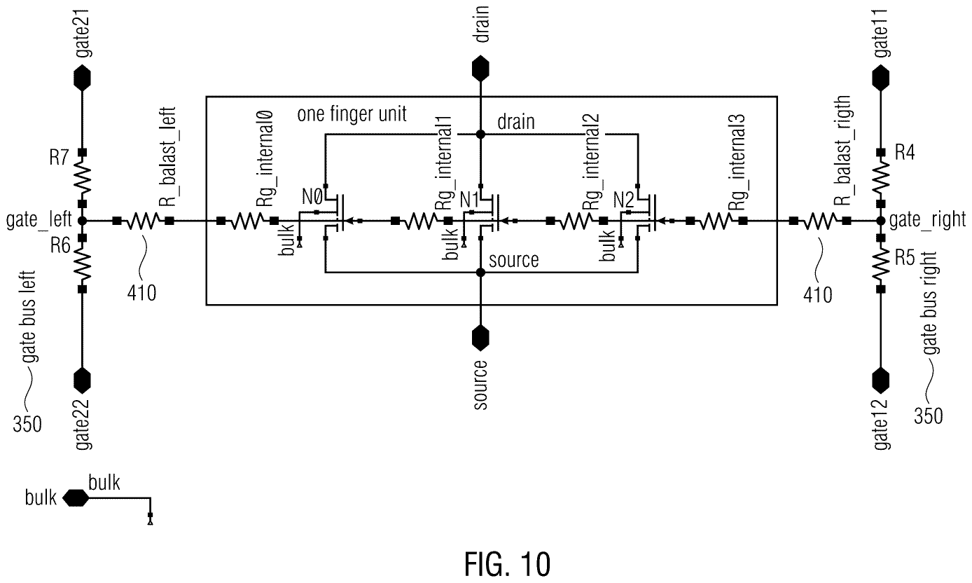

Next, reference is made to FIG. 10 showing a model for one finger unit with double-sided gate bus according to embodiments. The gate finger is modeled again as a series of transistors, wherein both ends of the gate finger unit are coupled via resistors 410 to the gate bus 350, or respectively opposite sided portions (e.g. a left and right portion) of the gate bus.

Hence, to sum up again:
For the low ohmics the I_{DSAT} performance does not scale anymore well below R_{dson} classes of 35 mOhm, typical in Gen2 (e.g. GaN, generation 2 devices). The absolute I_{DSAT} is comparable to Gen1 (e.g. GaN, generation 1 devices). Furthermore, any improvement so far, like the ring bus, just worked out in the small dies and high ohmic's which are in small packages. With the given packages and designs of today's state of the art, it is not feasible to make superior products without the modifications according to embodiments. Hence, using other approaches either a lot of saturation current is sacrificed by using the high ohmic single-sided gate bus, where the risk of internal oscillations is very high (legacy GaN-System had this problem in the past too), or the device may not be controllable anymore (or in other words, the stability of the device may not be guaranteed). Furthermore, other approaches comprising a capacitive behaving gate connection (microstrip) for solving the above problems, have the disadvantage of consuming a lot of chip area, e.g. ~20%. However, in contrast, embodiments discussed herein may solve some or even all of the above problems.

In particular, embodiments allow for an easier driving of the power transistor in the system, so that less possible EMI issues may occur, due to ringing, for example, ringing above >30 MHz. Therefore, embodiments propose, as an optional feature, a new layering of a respective chip comprising said plurality of resistors. Moreover, embodiments allow solving GIT-GaN specific problems, e.g. in particular the above-discussed problems.

### G

In other words, in Gen1 the chip size was never so big as it is planned to have in Gen2. For example: The biggest Gen1 chip was in the range of a 35 mΩ ~8 mm² the biggest Gen2 planned so far is in the range of <10 mΩ so almost >25 mm². At this big chip sizes the IDSAT does not scale anymore linear.

Regarding the statement that for the low-ohmic's, with Gen2 a significant cost down was achieved but the IDSAT performance is slightly lower then in Gen1 (e. g in the 35 mOhm RDSON class). (e.g. GaN, generation 1 devices), the following may be noted or considered: The performance may be increased a lot, but the relative performance of Gen 2 may only scale until a certain chip size, e.g. ~10 mm², and then the IDSAT performance does not scale anymore linear. As an example: Let us say a 25 mOhm product which is 34% bigger than a 35 mΩ product will only have an increase of IDSAT of 31% instead of 34%, and this trend is going on. So, a 17 mΩ product, which should have 2 times the IDSAT may show only 60% more IDSAT. So, the absolute performance may not be the problem, instead the problem may be more the scalability.

As another detail, the 35 mOhm product may, for example, have a spec (e.g. specification) which says IDS, max is 97 A but the device will be capable in the test up to 140 A, with few % spread, so one may be well above the targets, but if one scales this up to 17 mOhm or even down 10 mOhm devices this margin can be become too small, and needs to be understood and solved, in terms to come to the same margin again.

Reliability may be the major concern here, if the scaling fails, also a lot of assumptions which go along may need to be re-evaluated for any ohmic class of the big chips.

The above may be considered a starting point for an investigation leading to the embodiments disclosed herein, namely an investigation about where other approaches lose the performance.

In this regard (e.g. performance-loss-wise) one significant part was the gate bias, the next one is the metallization resistance for long fingers (e.g. fingers having a large finger width (hence devices with a large channel width)) in the power path (which may be easier or even much easier to simulate). During this investigation, embodiments comprising the double-sided gate bus were developed, and respective problems like instability solved or at least addressed.

It was also recognized that even paralleling chips, when one mixes the impedances and current directions of the signaling, the system may become instable, and (e.g. only) a damping can solve it. So even the single sided gate bus can be unstable. That is why the resistor (or respectively plurality of resistors) according to embodiments is strongly recommended to be used to mitigate the issues.

Hence, embodiments tackle or may address different levels of problems:
First, the problem about the current densities in the diode forward current state of the gate. These diode current densities of the different finger widths (which may also be considered finger lengths) may be matched by using the resistors, e.g. 410. Also, the inactive gate finger currents may be reduced, for example, by one order of magnitude, which may increase the gate overdrive of all other active gate fingers. This may hence increase the saturation current capability, for example, by almost 7% in measurements done on a FIB-cut device.
Second, the problem about the ringing. To understand the total effect of the ringing multiple things have to be considered, from inside out. The intrinsic speed of transistors, such as GaN transistors, is very high, so any frequency beyond GHz may be or will be amplified. The metallization of the gate inside the transistor may, for example, be fairly high ohmic, which may lead to some specific damping or attenuation, but may also reduce the current capability at low frequencies and DC. The travel times of the signals inside the gate metallization on the transistors themselves are all very different in the current designs, but the signal runtime difference from on finger to the next is, e.g. substantially, the same, so a beating may be very likely to occur too. This internal ringing can be strongly seen in some special gate bus versions, where also reflection runtime differences are amplified. The integration concept and packaging may add a lot of parasitic inductance, which may form many different LRC-oscillators (see e.g. FIG. 2). This resistor may introduce a damping which may damp or attenuate not only the input peak on the gate like an external resistor, it may also damp or attenuate all reflected waves coming from each finger back on the gate bus, so a ringing caused by the reflected wave may be damped or attenuated too. This kind of technique is novel in this field of application with the addition of the DC saturation current increase. The resistors according to embodiments can be made in any resistive material, which works in the area of the used gate drive voltages as valid impedance. Hence, in particular, the resistors may be arranged within a respective package, e.g. in a layer of the device stack. Accordingly, one important aspect of embodiments, e.g. one of its novelties, may be considered the field of application (e.g. oscillation topic), and also improving performance in GIT GaN (I_{DSAT} topic).

In this regard, it is to be noted that in general, according to embodiments, the semiconductor device may be a gate injection transistor. Furthermore, as another optional feature, the semiconductor device according to embodiments may be a Gallium nitride, GaN, transistor, or the semiconductor device may be a Silicon carbide, SiC, transistor. For example, the semiconductor device according to embodiments may have an active area which is larger than 1 mm². However, this size information (>1 mm²) may be understood as an example (e.g. an approximation), for a power device according to embodiments. Embodiments may address or comprise structures which are smaller, e.g. having the same problems as respectively larger structures, wherein said problems may be solved or at least mitigated using the resistors according to embodiments.

Furthermore, it is to be noted that the resistors may, for example, be on chip resistors, hence for example on a same chip surface as the gate fingers, source fingers and drain fingers, e.g. arranged within the package and within the transistor itself.

Reference is made again to FIG. 4. Further embodiments comprise a method for manufacturing a semiconductor device, e.g. transistor. The method comprises providing a gate node, a drain node, a source node and a gate bus 350, wherein the gate bus is connected to the gate node. The method further comprises providing a plurality of replication units 340, wherein a respective replication unit of the plurality of replication units comprises a gate finger 310, a source finger 320 and a drain finger 330 (wherein a finger may, for example, be a structure with an oblong shape, e.g. a structure, which is distinctly longer in one dimension than in its other dimensions. Gate fingers 310, source fingers 320 and drain fingers 330 are arranged in an interleaved manner (e.g. in an interlocking manner; e.g. in an interwoven manner, e.g. in parallel, e.g. next to each other, e.g. in an intertwining manner, e.g. in a structure in which individual comb-like fingers are arranged next to each other in an interwoven or interlocking or intertwining manner, e.g. like teeth of two gearwheels), in order to form a transistor structure, e.g. a lateral transistor structure. In addition, source fingers are coupled to the source node and drain fingers are coupled to the drain node, e.g. as shown in FIGS. 1 and 2. The method further comprises providing a plurality of resistors 410, e.g. a resistor network, wherein each resistor 410 connects one, e.g. at least one, of the gate fingers (e.g. a respective gate finger comprising two parallel gate finger substructures) to the gate bus 350.

Furthermore, as a general remark, it is to be noted that embodiments are not limited to interleaved finger structures as shown in FIG. 4. The plurality of resistors according to embodiments may be introduced or implemented for any transistor structure, e.g. lateral transistor structures, as well as vertical transistor structures.

Accordingly, embodiments comprise semiconductor devices with a source structure and drain structure, which are not necessarily finger shaped. Hence, such a device comprises a gate node, a drain node, a source node and a gate bus, wherein the gate bus is connected to the gate node. The source structure is coupled to the source node and the drain structure is coupled to the drain node. Such a device further comprises a plurality of replication units, wherein a respective replication unit of the plurality of replication units comprises a gate finger. The replication units may be arranged side by side or above and below one another, for example laterally or vertically, in order to form a larger transistor structure. Hence, the gate fingers, the source structure and the drain structure may be arranged to form a transistor structure. Optionally, a respective replication unit may comprise a source substructure and/or a drain substructure. Furthermore, as explained above a device according to embodiments comprises a plurality of resistors, wherein each resistor connects one of the gate fingers to the gate bus.

Hence, referring to FIG. 4. optionally, a respective replication unit of the plurality of replication units may comprise a source finger 320 and a drain finger 330, wherein gate fingers, source fingers and drain fingers are arranged in an interleaved manner, in order to form the transistor structure. Accordingly, in this case, source fingers are coupled to the source node and drain fingers are coupled to the drain node. Hence, the source structure may comprise or may be implemented in the form of the source fingers and the drain structure may comprise or may be implemented in the form of the drain fingers.

Hence, embodiments are not limited to lateral transistor structures, such as GaN, but may address or comprise vertical transistor structures, such as SiC, as well. Accordingly, the resistors according to embodiments may be implemented in any suitable transistor layout, e.g. comprising a plurality of gate fingers. Hence, conventional layouts may be adapted in that the plurality of resistors is introduced between respective gate fingers and the gate bus. Embodiments are not limited to any specific shape or form of source and drain areas.

As discussed previously, ringing in large chips (GaN general) is a problem for conventional designs. Internal ringing may be characterized or caused by very high frequencies and signal reflections. External ringing may be present for LRC of Gate loop (~30 MHz up to 100 MHz) and LRC of power loop (low freq., 100 KHz up to 10 MHz). Furthermore, according to conventional designs, an I_{dsat} loss may occur due to dead gate finger. This may be GaN “GIT” specific. In addition, in this technical field, parallelization of chips (chip embedding), e.g. of SiC/GaN modules, may be important.

In view of these problems and constraints:
Embodiments may allow a smooth-even-turn on of all active area, e.g. even for highly parallelized architectures, for example, by matching time constants and signal length (Example: ~10 ps/mm->large dies gate signal delay up to 100 ps; Cin of a 800 μm finger ~1 pF ; 5×τ=100 ps->ΔR=20 Ohm)

Hence, embodiments may allow matching resistances of the path, source and load, e.g. using the different gate bus designs and ohmic resistors according to embodiments. The resistors may, for example, be individually placed for each gate finger (e.g. multiple of 2) and may hence solve or help to solve some or even all of the above topics. Total resistance values may, for example, be in the range of 0.5 Ohm up to 10 Ohm for chip embedding (parallelization). According to further embodiments, e.g. as indicated in FIG. 9, the resistors may optionally comprise resistances of at least 100 Ω and at most 1000 Ω.

Hence, embodiments, e.g. compared to conventional approaches, may comprise adding a resistor per unitcell (e.g. gate finger) of a fast power transistor design (e.g. GaN, SiC) to mitigate or to improve or to reduce ringing issues and inactive gate diode I_{DSAT} reduction (e.g. GIT specific), via a direct chip embedding (e.g. no external resistor needed anymore (power modules parallelization of multiple chips)), enabling a matching of signal time across the whole chip for an even turn on/turn off event.

In general, embodiments may be used in the application area of power & sensor systems, e.g. for power technology comprising GaN and/or SiC architectures.

Embodiments will be summarized in the following as examples:

### Example 1

Semiconductor device, e.g. 200, comprising: a gate node, e.g. 210, a drain node, e.g. 220, a source node, e.g. 230, and a gate bus, e.g. 350, wherein the gate bus is connected to the gate node, a source structure, and a drain structure, wherein the source structure is coupled to the source node and wherein the drain structure is coupled to the drain node, a plurality of replication units, wherein a respective replication unit of the plurality of replication units comprises a gate finger, e.g. 310; wherein the gate fingers, the source structure and the drain structure are arranged to form a transistor structure, and a plurality of resistors, e.g. 410, wherein each resistor connects one of the gate fingers to the gate bus.

### Example 2

Semiconductor device, e.g. 200, according to example 1, wherein the source structure comprises a plurality of source fingers, e.g. 320; wherein the drain structure comprises a plurality of drain fingers, e.g. 330; wherein a respective replication unit, e.g. 340, of the plurality of replication units comprises a gate finger, a source finger, e.g. 320, and a drain finger, e.g. 330; wherein the gate fingers, the source fingers and the drain fingers are arranged in an interleaved manner, in order to form the transistor structure, wherein the source fingers are coupled to the source node and wherein the drain fingers are coupled to the drain node.

### Example 3

Semiconductor device according to example 1 or 2, wherein the gate bus, e.g. 350, comprises a plurality of gate bus junctions, e.g. 420, wherein a respective resistor, e.g. 410, is arranged between a respective gate bus junction and a respective gate finger, e.g. 310.

### Example 4

Semiconductor device according to any of the preceding examples, wherein a resistance of a respective resistor, e.g. 410, is set in dependence on a size of a respective gate finger, e.g. 310, in order to match current densities between different gate fingers having different gate finger sizes.

### Example 5

Semiconductor device according to any of the preceding examples, wherein the resistors, e.g. 410, are configured to mitigate oscillations above 30 MHz.

### Example 6

Semiconductor device according to any of the preceding examples, wherein a set of replication units, e.g. 340, is arranged side by side in a common plane, wherein the set of replication units comprises a first gate finger at a first side of the set of replication units and a last gate finger at a second side, opposite to the first side of the set of replication units, within the common plane; wherein the first gate finger and the last gate finger respectively only have one neighboring gate finger in the common plane; and wherein the resistors, e.g. 410, connected to the gate fingers, e.g. 310, of the set of replications units are configured to mitigate differences between input resistances of gate fingers between the first and last gate finger and of the first and last gate finger.

### Example 7

Semiconductor device according to any of the preceding examples, wherein the resistors, e.g. 410, are configured to adapt gate signal runtime differences for the gate fingers, e.g. 310.

### Example 8

Semiconductor device according to any of the preceding examples, wherein the resistors, e.g. 410, are configured to mitigate gate signal runtime differences for the gate fingers, e.g. 310.

### Example 9

Semiconductor device according to any of the preceding examples, wherein the semiconductor device comprises a diffusion barrier layer, and wherein the resistors, e.g. 410, are arranged in the diffusion barrier layer.

### Example 10

Semiconductor device according to any of the preceding examples, wherein the gate fingers, e.g. 310, are coupled to the gate bus, e.g. 350, via at least two connection paths, in order to improve potential distributions in the gate fingers.

### Example 11

Semiconductor device according to examples 10, wherein the plurality of resistors comprises a first subset, e.g. 510, of resistors, e.g. 410; wherein the plurality of resistors comprises a second subset, e.g. 520, of resistors, e.g. 410, wherein a respective gate finger, e.g. 310, comprises a first end and a second end, wherein the second end is lengthwise opposite to the first end; and wherein each resistor of the first subset of resistors connects a first end and each resistor of the second subset of resistors connects a second end of one of the gate fingers to the gate bus, in order to improve potential distributions in the gate fingers.

### Example 12

Semiconductor device according to examples 11, wherein a respective gate finger, e.g. 310, comprises an electrical interruption, e.g. 810, between the first and second end.

### Example 13

Semiconductor device according to any of the preceding examples, wherein the semiconductor device is a gate injection transistor.

### Example 14

Semiconductor device according to any of the preceding examples, wherein the semiconductor device is a Gallium nitride, GaN, transistor, or wherein is the semiconductor device is a Silicon carbide, SiC, transistor.

### Example 15

Semiconductor device according to any of the preceding examples, wherein an active area of the semiconductor device is larger than 1 mm².

### Example 16

Semiconductor device according to any of the preceding examples, wherein the resistors are on chip resistors.

### Example 17

Method for manufacturing a semiconductor device, e.g. 200, the method comprising: providing a gate node, e.g. 210, a drain node, e.g. 220, a source node, e.g. 230, a gate bus, e.g. 350, a source structure and a drain structure; connecting the gate bus to the gate node, coupling the source structure to the source node and coupling the drain structure to the drain node, providing a plurality of replication units, e.g. 320, wherein a respective replication unit of the plurality of replication units comprises a gate finger, e.g. 310; wherein the gate fingers, the source structure and the drain structure are arranged to form a transistor structure, and providing a plurality of resistors, e.g. 410, wherein each resistor connects one of the gate fingers to the gate bus.

### Example 18

Semiconductor device comprising: a gate node, e.g. 210, a drain node, e.g. 220, a source node, e.g. 230, and a gate bus, e.g. 350, wherein the gate bus is connected to the gate node, a plurality of replication units, e.g. 320, wherein a respective replication unit of the plurality of replication units comprises a gate finger, e.g. 310, a source finger, e.g. 320, and a drain finger, e.g. 330, wherein gate fingers, source fingers and drain fingers are arranged in an interleaved manner, in order to form a transistor structure, wherein source fingers are coupled to the source node and wherein drain fingers are coupled to the drain node, and a plurality of resistors, e.g. 410, wherein each resistor connects one of the gate fingers to the gate bus.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

The above-described embodiments are merely illustrative for the principles of embodiments. It is understood that modifications and variations of the arrangements and the details described herein will be apparent to others skilled in the art. It is the intent, therefore, to be limited only by the scope of the impending patent claims and not by the specific details presented by way of description and explanation of the embodiments herein.

1. A semiconductor device comprising:
a gate node, a drain node, a source node and a gate bus, wherein the gate bus is connected to the gate node,
a source structure and a drain structure, wherein the source structure is coupled to the source node and wherein the drain structure is coupled to the drain node,
a plurality of replication units,
wherein a respective replication unit of the plurality of replication units comprises a gate finger;
wherein the gate fingers, the source structure and the drain structure are arranged to form a transistor structure, and
a plurality of resistors,
wherein each resistor connects a respective one of the gate fingers to the gate bus.

2. The semiconductor device according to claim 1,
wherein the source structure comprises a plurality of source fingers;
wherein the drain structure comprises a plurality of drain fingers;
wherein a respective replication unit of the plurality of replication units comprises a gate finger, a source finger and a drain finger;
wherein the gate fingers, the source fingers and the drain fingers are arranged in an interleaved manner, in order to form the transistor structure,
wherein the source fingers are coupled to the source node and wherein the drain fingers are coupled to the drain node.

3. The semiconductor device according to claim 1,
wherein the gate bus comprises a plurality of gate bus junctions, wherein a respective resistor is arranged between a respective gate bus junction and a respective gate finger.

4. The semiconductor device according to claim 1
wherein a resistance of a respective resistor is set in dependence on a size of a respective gate finger, in order to match current densities between different gate fingers having different gate finger sizes.

5. The semiconductor device according to, claim 1
wherein the resistors are configured to mitigate oscillations above 30 MHz.

6. The semiconductor device according to claim 1,
wherein a set of replication units is arranged side by side in a common plane, wherein the set of replication units comprises a first gate finger at a first side of the set of replication units and a last gate finger at a second side, opposite to the first side of the set of replication units, within the common plane;
wherein the first gate finger and the last gate finger respectively only have one neighboring gate finger in the common plane; and
wherein the resistors connected to the gate fingers of the set of replications units are configured to mitigate differences between input resistances of gate fingers between the first and last gate finger and of the first and last gate finger.

7. The semiconductor device claim 1,
wherein the resistors are configured to adapt gate signal runtime differences for the gate fingers.

8. The semiconductor device according to claim 1,
wherein the resistors are configured to mitigate gate signal runtime differences for the gate fingers.

9. The semiconductor device according to claim 1
wherein the semiconductor device comprises a diffusion barrier layer, and
wherein the resistors are arranged in the diffusion barrier layer.

10. The semiconductor device according to claim 1,
wherein the gate fingers are coupled to the gate bus via at least two connection paths, in order to improve potential distributions in the gate fingers.

11. The semiconductor device according to claim 10,
wherein the plurality of resistors comprises a first subset of resistors;
wherein the plurality of resistors comprises a second subset of resistors,
wherein a respective gate finger comprises a first end and a second end, wherein the second end is lengthwise opposite to the first end; and
wherein each resistor of the first subset of resistors connects a first end and each resistor of the second subset of resistors connects a second end of one of the gate fingers to the gate bus, in order to improve potential distributions in the gate fingers.

12. The semiconductor device according to claim 11,
wherein a respective gate finger comprises an electrical interruption between the first and second end.

13. The semiconductor device according to claim 1,
wherein the semiconductor device is a gate injection transistor.

14. The semiconductor device according to claim 1,
wherein the semiconductor device is a Gallium nitride, GaN, transistor, or
wherein is the semiconductor device is a Silicon carbide, SiC, transistor.

15. The semiconductor device according to claim 1,
wherein an active area of the semiconductor device is larger than 1 mm².

16. The semiconductor device according to claim 1,
wherein the resistors are on chip resistors.

17. A method for manufacturing a semiconductor device, the method comprising:
providing a gate node, a drain node, a source node, a gate bus, a source structure and a drain structure;
connecting the gate bus to the gate node,
coupling the source structure to the source node and coupling the drain structure to the drain node,
providing a plurality of replication units,
wherein a respective replication unit of the plurality of replication units comprises a gate finger;
wherein the gate fingers, the source structure and the drain structure are arranged to form a transistor structure, and
providing a plurality of resistors,
wherein each resistor connects one of the gate fingers to the gate bus.
